(19) United States
(12) Patent Application Publication
(10) Pub. No.: US 2010/0106269 A1
(43) Pub. Date: Apr. 29, 2010

(54) METHOD AND APPARATUS FOR SIGNAL PROCESSING USING TRANSFORM-DOMAIN LOG-COMPANDING

(75) Inventors: Harinath Garudadri, San Diego, CA (US); Yen-Liang Shue, Los Angeles, CA (US); Somdeb Majumdar, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/428,336

(22) Filed: Apr. 22, 2009

Related U.S. Application Data
(60) Provisional application No. 61/100,645, filed on Sep. 26, 2008.
(60) Provisional application No. 61/101,070, filed on Sep. 29, 2008.

(51) Int. Cl. G06F 17/00; H04R 1/10; H04B 1/034; H03M 7/00; G04B 47/00; G10L 19/00

(52) U.S. Cl. 700/94; 381/370; 455/95; 341/107; 368/10; 704/E19.001; 704/203

(57) ABSTRACT

A method and apparatus for audio signal processing by applying log companding on spectral domain or time domain representations of the audio signals to provide an encoded audio signal, which is decoded upon receipt. A frequency domain representation or time domain representation of the audio signal is computed by separating the audio signal into specific frequency bands, each having a coefficient. Log companding with different compression ratios is performed on each coefficient to provide an encoded signal. Upon receipt of the encoded signal, inverse log companding and time frequency or time scale reconstruction are performed to provide the audio signal.

### CLAIM OF PRIORITY UNDER 35 U.S.C. §119

The present application for patent claims priority to Provisional Application No. 61/100,645 (Attorney Docket No. 082855P1), entitled “Transform-Domain Log Companding,” filed Sep. 26, 2008, and to Provisional Application No. 61/101,070, entitled “Transform-Domain Log Companding,” filed Sep. 29, 2008 (Attorney Docket No. 082855P2). Each of the preceding applications is assigned to the assignee hereof and hereby expressly incorporated by reference herein.

### BACKGROUND

1. Field

The present disclosure relates generally to communications, and more specifically, to signal compression using spectral domain log companding.

2. Background

Transmission of audio, such as voice and music, by digital techniques has become widespread, particularly in long distance telephony, packet-switched telephony such as Voice over Internet Protocol (VoIP), and digital radio telephony such as cellular telephony. Such proliferation has created an interest in reducing the amount of information used to transfer a voice communication over a transmission channel while maintaining the perceived quality of the reconstructed speech. For example, it is desirable to make the best use of available wireless system bandwidth. One way to use system bandwidth efficiently is to employ signal compression techniques. For wireless systems that carry speech signals, speech compression (or “speech coding”) techniques are commonly employed for this purpose. The techniques described here are applicable to other signals such as biomedical signals for healthcare and fitness applications.

Devices that are configured to compress speech by extracting parameters that relate to a model of human speech generation are often called “voice coders”, “vocoders”, “audio coders,” “speech coders,” or “codecs.” A codec generally includes an encoder and a decoder. The encoder typically divides the incoming speech signal (a digital signal representing audio information) into segments of time called “frames,” analyzes each frame to extract certain relevant parameters, and quantizes the parameters into an encoded frame. The encoded frames are transmitted over a transmission channel (i.e., a wired or wireless network connection) to a receiver that includes a decoder. The decoder receives and processes encoded frames, dequantizes them to produce the parameters, and recreates speech frames using the dequantized parameters.

Traditional audio/speech compression methods rely on complex psychoacoustic models to achieve significant compression while maintaining a high level of quality. Traditional audio compression methods, such as the MPEG-1 Audio Layer 3 (MP3) and Advanced Audio Coding (AAC) schemes, are typically based on psychoacoustic models that rely on information about the human auditory system. These schemes are able to achieve significant compression (e.g., bit rates approximately 1/10th of the original signal), while maintaining a level of reproduction quality that is close to the quality level of the original, uncompressed content. However, while achieving these large compression ratios, these methods are complex, come at the cost of high power consuming compression/uncompression circuitry, significant latency, and generally are not well suited to low power, low latency applications/devices. With the increase of bandwidth in modern devices, the requirement for heavy compression can be relaxed in exchange for low complexity encoding/decoding schemes.

Wireless headsets with hands-free operation are becoming increasingly commonplace in mobile telephony. The trend for short-range radio technologies in the context of body area networks (BAN) is to provide higher data rates with lower power consumption. The evolutionary trend for BAN radios involves low power radios that can achieve a few megabits/sec of throughput using only a few milliwatts (mW) of power consumption. In the context of BAN for wearable devices, it is desirable to increase the battery life, shrink form factors, and reduce cost.

In the context of conversational services, with the deployment of wideband codecs such as AMR-WB and EVRC-WB in 3G networks, there is a need to improve voice quality and reduce lower power in BAN. Similarly, for audio streaming services, there is a need to preserve wire-line quality with wireless headphones, so that the user experience is not compromised.

Consequently, it would be desirable to address one or more of the deficiencies described above.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In one aspect of the disclosure, a method for encoding is disclosed. The method includes receiving a data signal, performing a transform of the data signal to provide at least two coefficients, and performing log companding of the at least two coefficients to provide a compressed data signal.

In another aspect of the disclosure, a method for decoding is disclosed. The method includes receiving a compressed data signal, performing expansion by inverse log companding of the compressed data signal to obtain at least two coefficients, and performing inverse transform on the at least two coefficients to provide a data signal.

In yet another aspect of the disclosure, an apparatus for encoding is disclosed. The apparatus includes a receiver configured to receive a data signal, a transform circuit configured to decompose the data signal to provide at least two coefficients, and a log companding circuit configured to encode the at least two coefficients to provide a compressed data signal.

In a further aspect of the disclosure, an apparatus for decoding is disclosed. The apparatus includes a receiver configured to receive a compressed data signal, an inverse log companding circuit configured to decode the compressed data signal to obtain at least two coefficients, and an inverse transform circuit configured to reconstruct a data signal from the at least two coefficients.

In yet a further aspect of the disclosure, an apparatus for encoding is disclosed. The apparatus includes means for receiving a data signal, means for performing a transform of the data signal to provide at least two coefficients, and means for performing log companding of the at least two coefficients to provide a compressed data signal.

In yet a further aspect of the disclosure, an apparatus for decoding is disclosed. The apparatus includes means for receiving a compressed data signal, means for performing inverse log companding by decoding the compressed data signal to obtain at least two coefficients, and means for performing inverse transform on the at least two coefficients to provide a data signal.

In yet a further aspect of the disclosure, a computer program product for encoding is disclosed. The computer program product includes a computer-readable medium comprising instructions executable to receive a data signal, perform a transform of the data signal to provide at least two coefficients, and perform log companding of the at least two coefficients to provide a compressed data signal.

In yet a further aspect of the disclosure, a computer program product for decoding is disclosed. The computer program product includes a computer-readable medium comprising instructions executable to receive a compressed data signal, perform inverse log companding by decoding the compressed data signal to obtain at least two coefficients, and perform inverse transform on the at least two coefficients to provide a data signal.

In yet a further aspect of the disclosure, a headset is disclosed. The headset includes a receiver configured to receive a compressed data signal; an inverse log companding circuit configured to decode the compressed data signal to obtain at least two coefficients; an inverse transform circuit configured to reconstruct a data signal from the at least two coefficients; and a transducer configured to provide audio output based on the reconstructed data signal.

In yet a further aspect of the disclosure, a sensing device is disclosed. The sensing device includes a sensor configured to detect a data signal; a transform circuit configured to decompose the data signal to provide at least two coefficients; a log companding circuit configured to encode the at least two coefficients to provide a compressed data signal; and a transmitter configured to transmit the compressed data signal.

In yet a further aspect of the disclosure, a handset is disclosed. The handset includes a transducer configured to detect an audio signal; a transform circuit configured to decompose the audio signal to provide at least two coefficients; a log companding circuit configured to encode the at least two coefficients to provide a compressed audio signal; and an antenna configured to transmit the compressed audio signal. In yet a further aspect of the disclosure, a watch is disclosed. The watch includes a receiver configured to receive a compressed data signal; an inverse log companding circuit configured to decode the compressed data signal to obtain at least two coefficients; an inverse transform circuit configured to reconstruct a data signal from the at least two coefficients; and a user interface configured to provide an indication based on the reconstructed data signal.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a diagram illustrating an example of a wireless network;

FIG. 2 is a block diagram illustrating a signal compression system configured in accordance with various aspects disclosed herein;

FIGS. 3A-3C are plots of example probability distributions of the first, second and sixth Discrete Cosine Transform (DCT) coefficients, respectively, in accordance with various aspects of the disclosure;

FIGS. 4A and 4B are flow diagrams illustrating encoding/decoding functions performed in accordance with aspects of the disclosure;

FIG. 5 is a block diagram illustrating a system for facilitating speech/audio signal processing in a wireless network, in accordance with aspects of the disclosure;

FIG. 6 is a block diagram illustrating a receiver for facilitating improved wireless audio/speech decoding, in accordance with aspects of the disclosure;

FIG. 7 is a block diagram illustrating a transmitter for facilitating speech/audio signal compression, in accordance with aspects of the disclosure;

FIG. 8 is a block diagram illustrating an encoding apparatus configured in accordance with aspects of the disclosure; and

FIG. 9 is a block diagram illustrating a decoding apparatus configured in accordance with aspects of the disclosure.

### DETAILED DESCRIPTION

Various aspects are described more fully hereinafter with reference to the accompanying drawings. Aspects disclosed herein may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect disclosed herein, whether implemented independently of or combined with any other aspect. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects set forth herein. It should be understood that any aspect disclosed herein may be embodied by one or more elements of a claim.

There is a need for a new class of high quality speech and audio solutions, for which low power is critical, compared to compression efficiency.

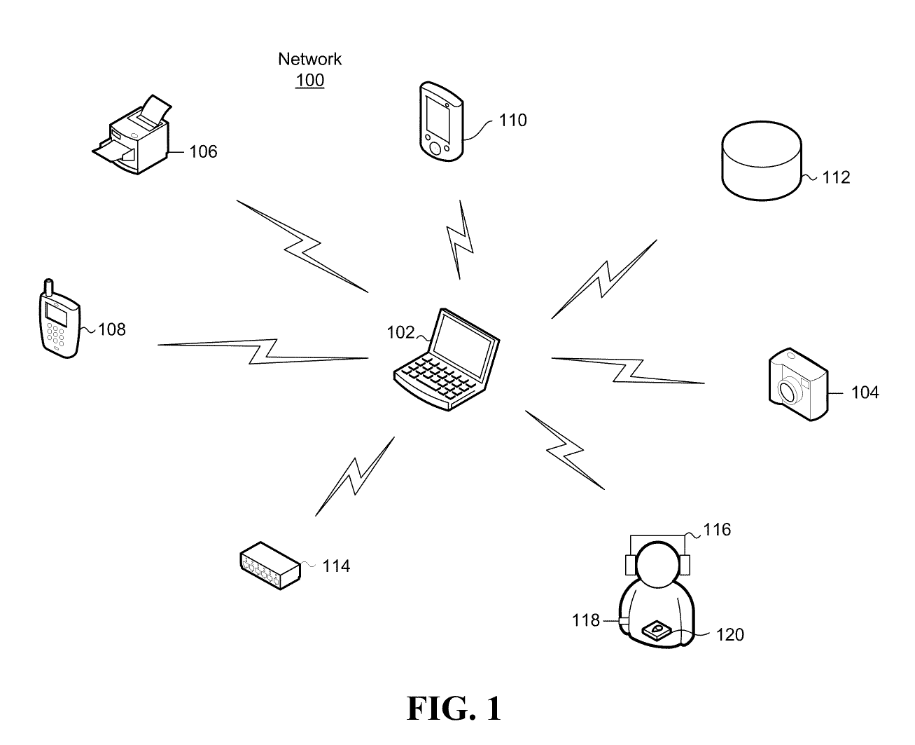

An example of a short range communications network suitable for supporting one or more aspects presented throughout this disclosure is illustrated in FIG. 1. The network 100 is shown with various wireless nodes that communicate using any suitable radio technology or wireless protocol. By way of example, the wireless nodes may be configured to support Ultra-Wideband (UWB) technology. Alternatively, the wireless nodes may be configured to support various wireless protocols such as Bluetooth or IEEE 802.11, just to name a few.

The network 100 is shown with a computer 102 in communication with the other wireless nodes. In this example, the computer 102 may receive digital photos from a digital camera 104, send documents to a printer 106 for printing, synch-up with e-mail on a personal digital assistant (PDA) 108, transfer music files to a digital audio player (e.g., MP3 player) 110, back up data and files to a mobile storage device 112, and communicate with a remote network (e.g., the Internet) via a wireless hub 114. The network 100 may also include a number of mobile and compact nodes, either wearable or implanted into the human body. By way of example, a person may be wearing a headset 116 (e.g., headphones, earpiece, etc.) that receives streamed audio from the computer 102, a watch 118 that is set by the computer 102, and/or a sensor 120 which monitors vital body parameters (e.g., a biometric sensor, a heart rate monitor, a pedometer, and EKG device, etc.).

Although shown as a network supporting short range communications, aspects presented throughout this disclosure may also be configured to support communications in a wide area network supporting any suitable wireless protocol, including by way of example, Evolution-Data Optimized (EV-DO), Ultra Mobile Broadband (UMB), Code Division Multiple Access (CDMA) 2000, Long Term Evolution (LTE), or Wideband CDMA (W-CDMA), just to name a few. Alternatively, the wireless node may be configured to support wired communications using cable modem, Digital Subscriber Line (DSL), fiber optics, Ethernet, HomeRF, or any other suitable wired access protocol.

In some aspects a wireless device may communicate via an impulse-based wireless communication link. For example, an impulse-based wireless communication link may utilize ultra-wideband pulses that have a relatively short length (e.g., on the order of a few nanoseconds or less) and a relatively wide bandwidth. In some aspects the ultra-wideband pulses may have a fractional bandwidth on the order of approximately 20% or more and/or have a bandwidth on the order of approximately 500 MHz or more.

The teachings herein may be incorporated into (e.g., implemented within or performed by) a variety of apparatuses (e.g., devices). For example, one or more aspects taught herein may be incorporated into a phone (e.g., a cellular phone), a personal data assistant (“PDA”), an entertainment device (e.g., a music or video device), a headset (e.g., headphones, an earpiece, etc.), a microphone, a medical sensing device (e.g., a biometric sensor, a heart rate monitor, a pedometer, an EKG device, a smart bandage, etc.), a user I/O device (e.g., a watch, a remote control, a light switch, a keyboard, a mouse, etc.), an environment sensing device (e.g., a tire pressure monitor), a monitor that may receive data from the medical or environment sensing device, a computer, a point-of-sale device, an entertainment device, a hearing aid, a set-top box, or any other suitable device.

These devices may have different power and data requirements. In some aspects, the teachings herein may be adapted for use in low power applications (e.g., through the use of an impulse-based signaling scheme and low duty cycle modes) and may support a variety of data rates including relatively high data rates (e.g., through the use of high-bandwidth pulses).

Various aspects or features will be presented in terms of systems that may include a number of devices, components, modules, and the like. It is to be understood and appreciated that the various systems may include additional devices, components, modules, etc., and/or may not include all of the devices, components, modules etc. discussed in connection with the figures. A combination of these approaches may also be used. As those skilled in the art will readily appreciate, the aspects described herein may be extended to any other apparatus, system, method, process, device, or product, currently implementing signal compression using transform-domain log-companding.

Aspects disclosed herein take advantage of the fact that the human ear is less sensitive to concealment of drop-outs in the frequency domain than to concealment of drop-outs in the time-domain. Thus, aspects disclosed herein apply equally well to a wide range of signals including audio, ultra-wideband speech, wideband speech and narrowband speech, among others.

Aspects of the disclosure provide a low-complexity, low-latency, and robust to channel errors solution to audio/speech compression that utilizes spectral domain log-companding (compression and expanding), and achieves transparent quality for wideband speech and audio. Aspects disclosed herein can be implemented with hardware friendly operations such as shift-and-adds, which require less power and area than traditional decoders.

Aspects disclosed herein approach signal compression by applying log companding on spectral domain representations of signals. Aspects of the disclosure combine these concepts by first computing the frequency domain representation of the signal. Transforms project data from one basis to another with the goal of representing the original data in a way which allows for the application of some psychoacoustic masking. Typically, this is done by separating a signal into specific frequency bands (interchangeably referred to herein as “bins”) through the use of transforms, as in the case of the MP3 encoder, for example.

Upon computing the spectral domain representations of the audio/speech signals, aspects of the disclosure perform log companding with different compression ratios on each spectral coefficient. Since very little audio/speech energy resides in the upper frequency bands, the allocation of very few bits in those bands can maintain good quality. The resulting average number of bits per sample can therefore be reduced and is scalable with audio/speech quality. In addition, since the signal is encoded in the spectral domain, if there are bursty channel errors, they affect frequency bands in the time-frequency plane rather than simple dropouts in time. These errors are much less disagreeable to the human ear and, when subjected to simple spectral domain interpolation, can be effectively concealed.

It will be recognized that the invention may be implemented by performing a transform in the time-scale domain, in addition to the time-frequency domain. An example of such a time-scale transform is a wavelet.

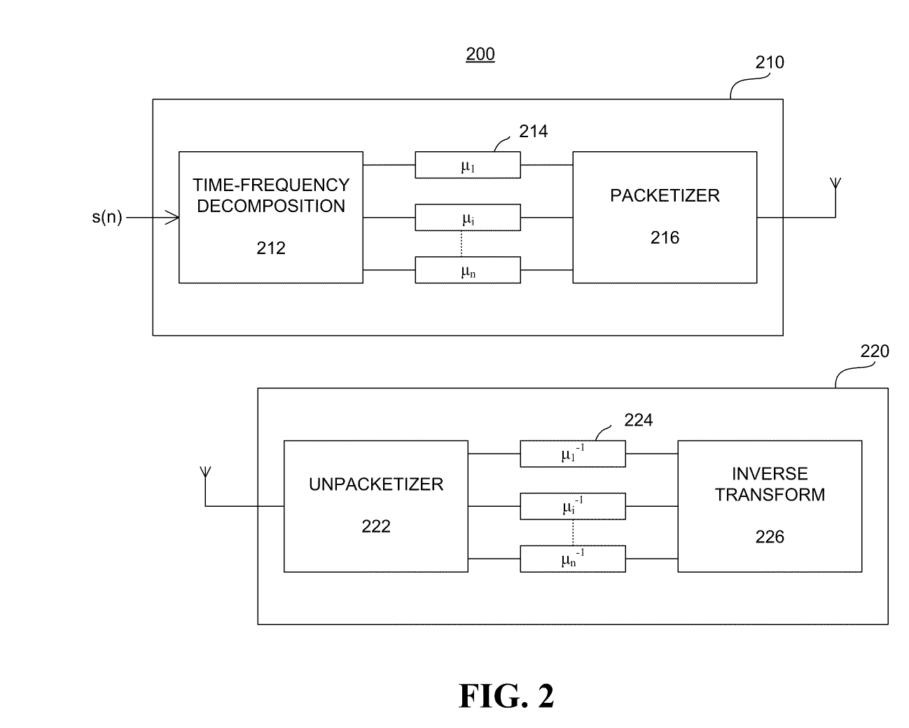

Referring now to FIG. 2, therein shown is a signal compression system 200 configured in accordance with various aspects disclosed herein. The system 200 includes an encoder 210 and a decoder 220. The encoder 210 includes a time-to-frequency decomposition block 212, a plurality of companders 214 and a packetizer 216. The decoder 220 includes an unpacketizer 222, a plurality of inverse companders 224, and an inverse transform block 226.

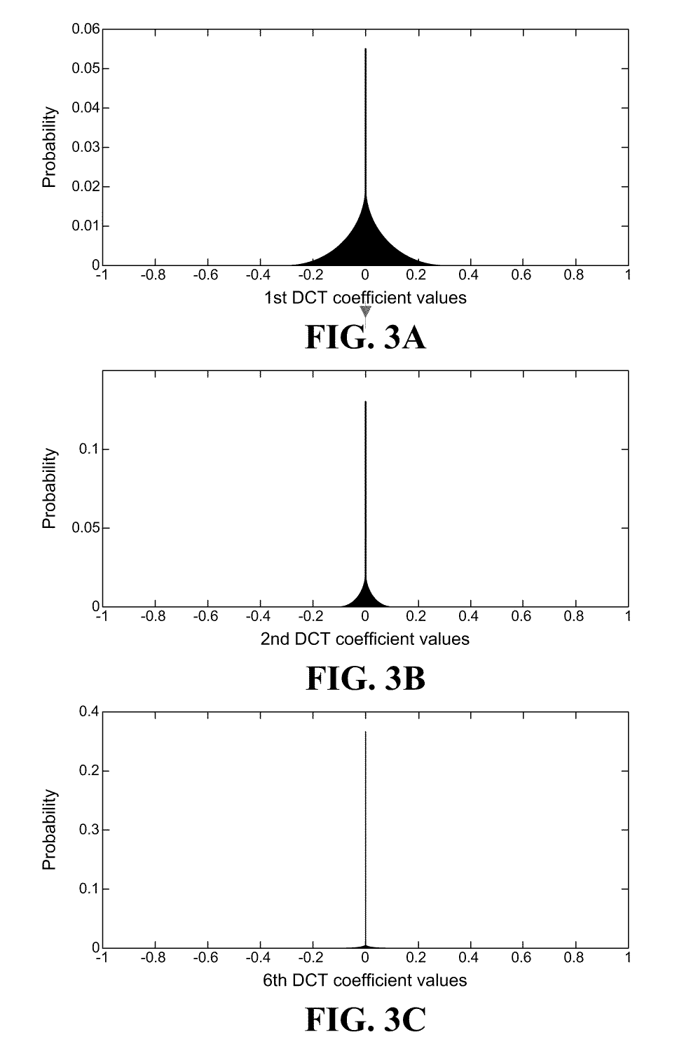

In accordance with one aspect, time-to-frequency decomposition block 212 uses a Discrete Cosine Transform (DCT) algorithm to decorrelate the input signal s(n) into multiple frequency bands, each having a spectral DCT coefficient. The DCT algorithm decorrelates the signal into multiple frequency bands or bins. For example, an 8-point DCT transform may be performed, although the point number may vary. It should be noted that the statistical distribution of each spectral coefficient is Laplacian in nature with much higher probability for lower amplitude coefficients, compared with higher amplitude coefficients. It should also be noted that for the upper spectral DCT coefficients, the variances of the coefficients significantly decrease. Example probability distributions of the first, second and sixth DCT coefficients, respectively, are shown in FIGS. 3A-3C. As can be seen from the example distributions in FIGS. 3A-3C, fewer bits may be allocated for the higher DCT coefficients. It should also be noted that although aspects have been described in reference to a DCT algorithm, any transform that decorrelates a signal into multiple frequency bands may be used to achieve similar results.

In accordance with one aspect of the disclosure, use of the DCT may be compared to classifying the energy of a signal into evenly divided frequency bands. For example, for data sampled at 32/48 kHz, the coefficients from an 8-point DCT could roughly represent the amount of energy at consecutive ⅔ kHz frequency bands to 16/24 kHz. It is known from psychoacoustic modeling that human hearing becomes less sensitive at frequencies above 16 kHz.

Log companding, such as the μ-law/A-law algorithm, is an efficient compression tool for signals having a Laplacian/Exponential distribution, and works well for signals, such as speech, that have a distribution that resembles a Laplacian distribution, despite having a wide dynamic range. In log companding, coarser quantization is used for larger sample values and progressively finer quantization is used for smaller sample values. This characteristic has been successfully exploited in telephony compression algorithms, e.g., G.711 specifications, which allow for intelligible transmission of speech at much lower bitrates (e.g., 8 bits per sample). The G.711 log companding (compression and expansion) specifications are described in the International Telecommunication Union (ITU-T) Recommendation G.711 (November 1988)—Pulse code modulation (PCM) of voice frequencies and in the G711.C, G.711 ENCODING/DECODING FUNCTIONS, and are incorporated herein in their entirety.

There are two G.711 log companding schemes: a μ-law companding scheme and an A-law companding scheme. Both the μ-law companding scheme and the A-law companding scheme are Pulse Code Modulation (PCM) methods. That is, an analog signal is sampled and the amplitude of each sampled signal is quantized, i.e., assigned a digital value. Both the μ-law and A-law companding schemes quantize the sampled signal by a linear approximation of the logarithmic curve of the sampled signal.

Both the μ-law and A-law companding schemes operate on a logarithmic curve. Therefore the logarithmic curve is divided into segments, wherein each successive segment is twice the length of the previous segment. The A-law and μ-law companding schemes have different segment lengths because the μ-law and A-law companding schemes calculate the linear approximation differently. It should be noted that although aspects have been described in reference to log companding using the G. 711 specifications, any log companding specification that allows intelligible transmission of speech at low bitrates may be used to achieve similar goals.

Referring again to FIG. 2, in accordance with one aspect, log companding, which operates on values between −1 and 1, is applied on the DCT coefficients by the plurality of log companders 214, each using a different companding parameter, such as a μ constant (μ₁ to μₙ). Log companding effectively allocates more quantization steps around 0, and less as the sample values increase. As speech/audio signals are sharper in the upper frequency bands (as can be seen from FIGS. 3A-3C), fewer bits can be allocated in those bands, while maintaining good quality. For example, the first, second, and third coefficients may be respectively scaled down by a factor of 4, 2 and 2, which ensures a correct data range for the plurality of log companders 214. In accordance with one aspect, clipping is performed on DCT coefficient values with a magnitude greater than 1.

The decoder 220, in accordance with the above variation, reverses the companding and DCT transform performed to compress the signal. After the received signal is unpacketized by unpacketizer 222, the first three coefficients are scaled up by 4, 2 and 2, respectively, and inverse log companding is performed in inverse companders 224. Inverse DCT transform is performed in Inverse Transform Block 226 to obtain a reconstructed time-frequency signal.

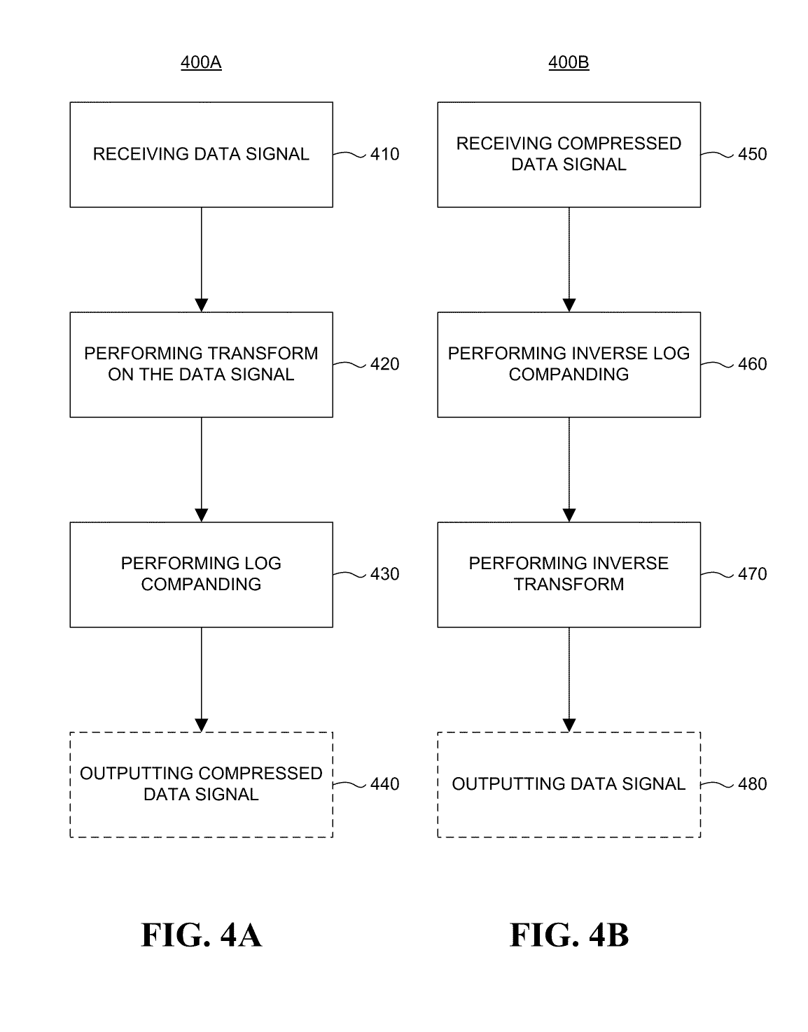

Referring now to FIGS. 4A and 4B, therein shown are flow diagrams of functions performed in accordance with aspects disclosed herein. Examples of functions performed in the encoder are shown in an encoding process 400A FIG. 4A. Upon receiving the data signal in step 410, a transform is performed in step 420 to achieve time-frequency decomposition of the signal. Log companding with different companding parameters, such as μ constants, is performed in step 430, and a compressed data signal is outputted in step 440.

Examples of functions performed in the decoder are shown in a decoding process 400B in FIG. 4B. Upon receiving a compressed data signal in step 450, inverse log companding is performed in step 460. Inverse transform is performed in step 470, and the data signal is output in step 480.

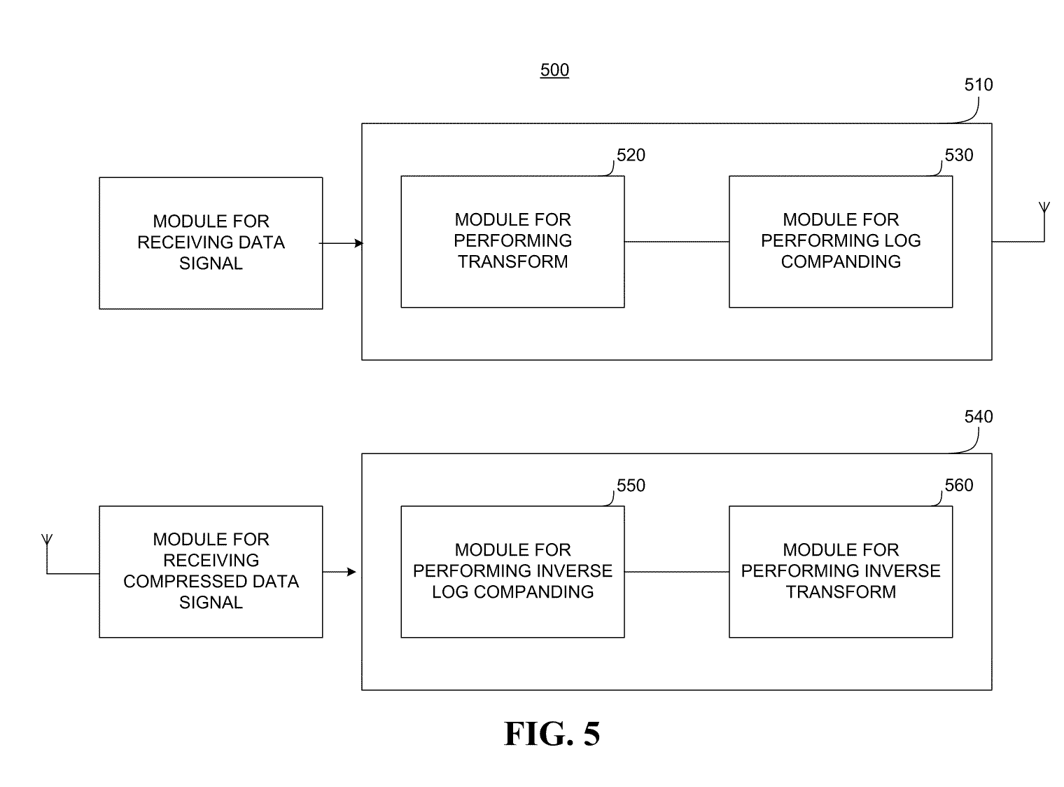

With reference to FIG. 5, therein illustrated is a system 500 that facilitates speech/audio signal processing in a wireless network, in accordance with various aspects.

System 500 may include an encoder 510 and a decoder 540, for example. Encoder 510 can reside at least partially within a base station, for example. It is to be appreciated that system 500 is represented as including functional blocks, which can be functional blocks that represent functions implemented by a processor, software, or combination thereof (e.g., firmware). Encoder 510 includes a logical grouping of electrical components 520, 530 that can act in conjunction. Decoder 540 also includes a logical grouping of electrical components 550, 560 that can act in conjunction.

For instance, logical grouping 520, 530 can include means for performing transform on a received speech/audio signal 520, which functions to perform time-frequency decomposition of the speech audio signal into multiple frequency bands. Further, logical grouping 520, 530 can comprise means for performing log companding 530, which functions to compress the signal by applying different compression ratios on each spectral coefficient for each frequency band. Additionally, logical grouping 520, 530 can include a memory (not shown) that retains instructions for executing functions associated with electrical components 520, 530.

Further, logical grouping 550, 560 can include means for performing inverse log companding 550, which functions to decode the signal by applying the inverse compression ratios, and means for inverse transform 560, which functions as a time-frequency reconstruction circuit to inverse the time-frequency decomposition of the signal.

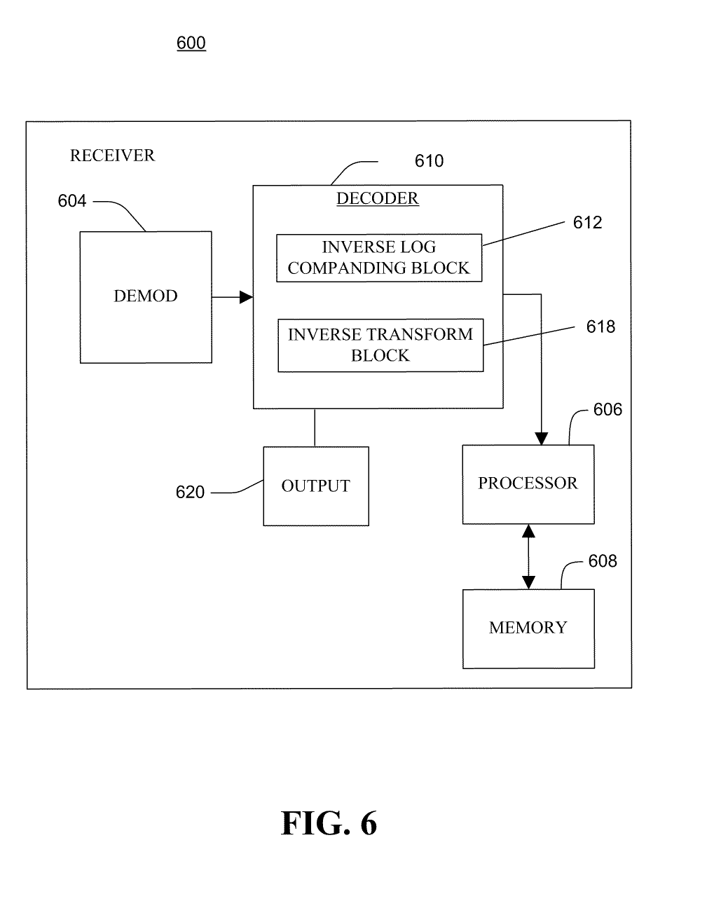

FIG. 6 is an illustration of a receiver 600 that facilitates improved wireless audio/speech decoding. Receiver 600 receives a signal from, for instance, a receive antenna (not shown), and performs typical actions thereon (e.g., filters, amplifies, downconverts, etc.) the received signal and digitizes the conditioned signal to obtain samples. Receiver 602 can comprise a demodulator 604 that can demodulate received symbols and provide them to a processor 606 for channel estimation. Processor 606 can be a processor dedicated to analyzing information received by receiver 600, a processor that controls one or more components of receiver 600, and/or a processor that both analyzes information received by receiver 600 and controls one or more components of receiver 600.

Receiver 600 can additionally comprise memory 608 that is operatively coupled to processor 606 and that may store data to be transmitted, received data, information related to available channels, data associated with analyzed signal and/or interference strength, information related to an assigned channel, power, rate, or the like, and any other suitable information for estimating a channel and communicating via the channel. Memory 608 can additionally store protocols and/or algorithms associated with estimating and/or utilizing a channel (e.g., performance based, capacity based, etc.). Additionally, the memory 608 may store executable code and/or instructions. For example, the memory 608 may store instructions for decompressing a received speech/audio signal. Further, the memory 608 may store instructions for performing inverse log companding to decode the signal by applying inverse encoding ratios, and for performing inverse transform to inverse the time-frequency decomposition of the signal.

It will be appreciated that the data store (e.g., memory 608) described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable PROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). The memory 608 of the subject systems and methods is intended to comprise, without being limited to, these and any other suitable types of memory.

Processor 606 is further operatively coupled to a decoder 610, in which an inverse log companding block 612 may perform inverse log companding to decode the signal by applying inverse compression ratios, and an inverse transform block 618 (e.g., a time-frequency reconstruction circuit) may perform inverse transform to inverse the time-frequency decomposition of the signal. The inverse log companding block 612 and/or inverse transform block 618 may include aspects as described above with reference to FIGS. 2-5 to obtain a time-frequency reconstructed signal. Although depicted as being separate from the processor 606, it is to be appreciated that inverse log companding block 612 and/or inverse transform block 618 may be part of processor 606 or a number of processors (not shown). An output block 620 provides the output from the processor 606.

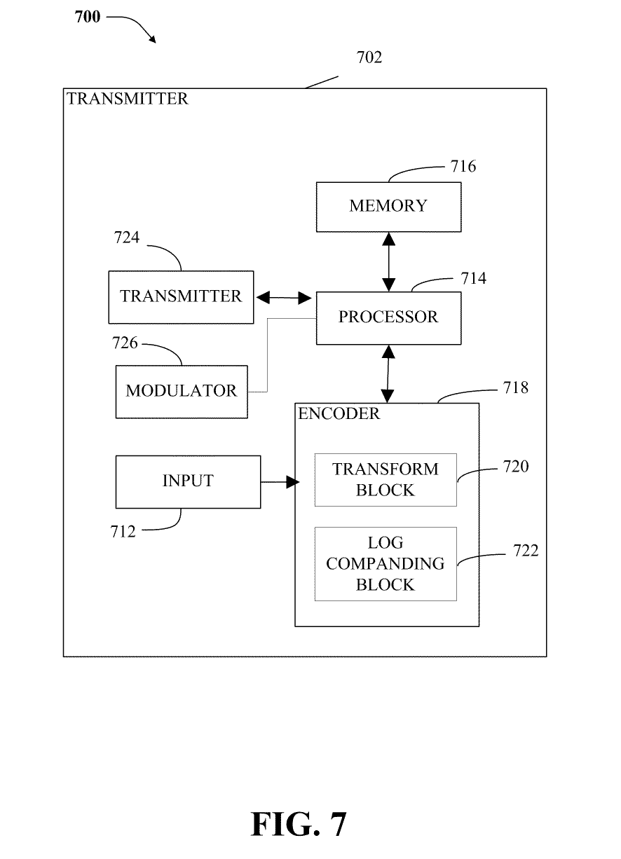

FIG. 7 is an illustration of an example transmitter system 700 that facilitates speech/audio signal compression, in accordance with aspects disclosed herein. System 700 comprises a transmitter 724 that transmits to the one or more mobile devices (not shown) through a plurality of transmit antennas (not shown). Input into the transmitter may be analyzed by a processor 714 that can be similar to the processor described above with regard to FIG. 6, and which is coupled to a memory 716 that stores information related to data to be transmitted to or received from mobile device(s) (not shown) or a disparate base station (not shown), and/or any other suitable information related to performing the various actions and functions set forth herein.

Processor 714 is further coupled to an encoder 718, in which a transform block 720 can perform time frequency decomposition of a received speech/audio signal, and a log companding block 722 can perform log companding to encode the signal by applying a different compression ratio on each spectral coefficient for each frequency band. The transform block 720 and/or log companding block 722 may include aspects as described above with reference to FIGS. 2-5. Information to be transmitted may be provided to a modulator 726. Modulator 726 can multiplex the information for transmission by a transmitter 724 through antenna (not shown) to mobile device(s) (not shown). Although depicted as being separate from the processor 714, it is to be appreciated that the transform block 720 and/or log companding block 722 may be part of processor 714 or a number of processors (not shown).

It should be noted that the receiver described in reference to FIG. 6 and the transmitter system described in reference to FIG. 7 may be combined in a single device (e.g., a mobile device) or may be separate parts of other devices (e.g., an earpiece or sensor that monitors vital bodily functions).

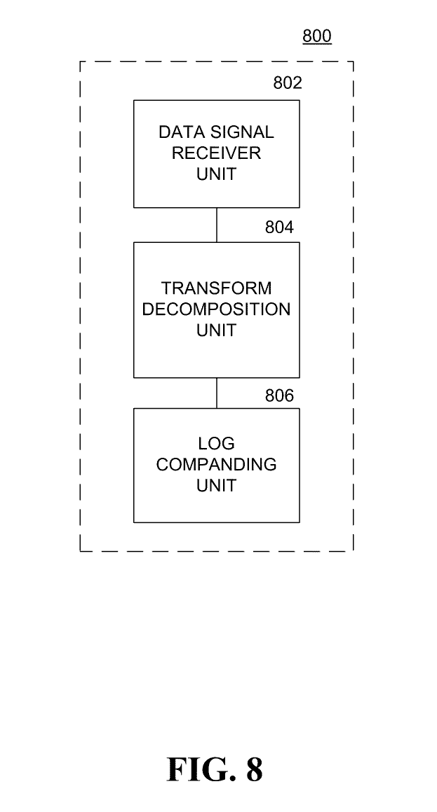

FIG. 8 illustrates an encoding apparatus 800 for encoding a data signal for a wireless communication device having various modules operable to encode the data signal using time-frequency decomposition and log companding. A data signal receiver 802 is used for receiving a data signal. A time-frequency decomposer 804 is configured to perform a time-frequency decomposition of the data signal to provide at least two spectral coefficients. A log compander 806 is configured to perform log companding of the at least two spectral coefficients to provide a compressed data signal.

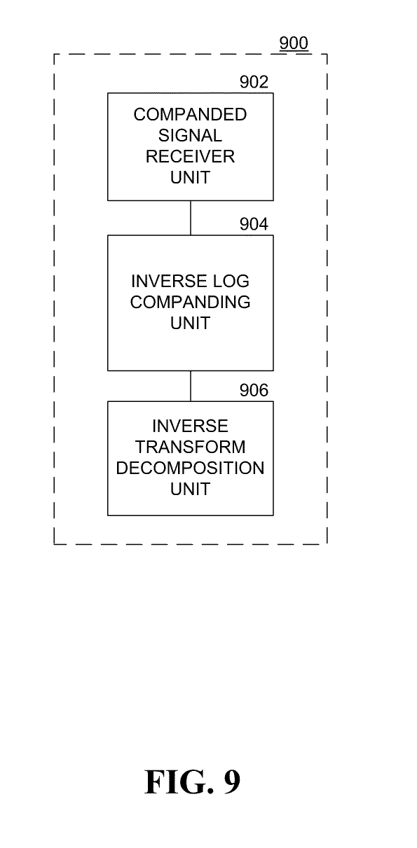

FIG. 9 illustrates a decoding apparatus 900 for decoding a data signal for a wireless communication device having various modules operable to decode the data signal using inverse log companding and inverse time-frequency decomposition. A compressed signal receiver 902 is used for receiving a compressed signal. An inverse log compander 904 is configured to perform inverse log companding by decoding the compressed data signal to obtain at least two spectral coefficients. A time-frequency decomposer 906 is configured to perform inverse time-frequency decomposition on the at least two spectral coefficients to provide a data signal.

The techniques described herein may be used for various wireless communication systems such as CDMA, TDMA, FDMA, OFDMA, SC-FDMA and other systems. The terms “system” and “network” are often used interchangeably. A CDMA system may implement a radio technology such as Universal Terrestrial Radio Access (UTRA), cdma2000, etc. UTRA includes Wideband-CDMA (W-CDMA) and other variants of CDMA. Further, cdma2000 covers IS-2000, IS-95 and IS-856 standards. A TDMA system may implement a radio technology such as Global System for Mobile Communications (GSM). An OFDMA system may implement a radio technology such as Evolved UTRA (E-UTRA), Ultra Mobile Broadband (UMB), IEEE 802.11 (Wi-Fi), IEEE 802.16 (WiMAX), IEEE 802.20, Flash-OFDM, etc. UTRA and E-UTRA are part of Universal Mobile Telecommunication System (UMTS). 3GPP Long Term Evolution (LTE) is a release of UMTS that uses E-UTRA, which employs OFDMA on the downlink and SC-FDMA on the uplink. UTRA, E-UTRA, UMTS, LTE and GSM are described in documents from an organization named “3rd Generation Partnership Project” (3GPP). Additionally, cdma2000 and UMB are described in documents from an organization named “3rd Generation Partnership Project 2” (3GPP2). Further, such wireless communication systems may additionally include peer-to-peer (e.g., mobile-to-mobile) ad hoc network systems often using unpaired unlicensed spectrums, 802.xx wireless LAN, BLUETOOTH and any other short- or long-range, wireless communication techniques.

In one or more aspects, the functions described may be implemented in hardware, software, firmware, or any combination thereof. If implemented in software, the functions may be stored or transmitted as one or more instructions or code on a computer-readable medium. Computer-readable media includes both computer storage media and communication media including any medium that facilitates transfer of a computer program from one place to another. A storage medium may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection may be termed a computer-readable medium. For example, if software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs usually reproduce data optically with lasers. Combinations of the above should also be included within the scope of computer-readable media.

The components described herein may be implemented in a variety of ways. For example, an apparatus may be represented as a series of interrelated functional blocks that may represent functions implemented by, for example, one or more integrated circuits (e.g., an ASIC) or may be implemented in some other manner as taught herein. As discussed herein, an integrated circuit may include a processor, software, other components, or some combination thereof. Such an apparatus may include one or more modules that may perform one or more of the functions described above with regard to various figures.

As noted above, in some aspects these components may be implemented via appropriate processor components. These processor components may in some aspects be implemented, at least in part, using structure as taught herein. In some aspects a processor may be adapted to implement a portion or all of the functionality of one or more of these components.

As noted above, an apparatus may comprise one or more integrated circuits. For example, in some aspects a single integrated circuit may implement the functionality of one or more of the illustrated components, while in other aspects more than one integrated circuit may implement the functionality of one or more of the illustrated components.

In addition, the components and functions described herein may be implemented using any suitable means. Such means also may be implemented, at least in part, using corresponding structure as taught herein. For example, the components described above may be implemented in an “ASIC” and also may correspond to similarly designated “means for” functionality. Thus, in some aspects one or more of such means may be implemented using one or more of processor components, integrated circuits, or other suitable structure as taught herein.

Also, it should be understood that any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be employed there or that the first element must precede the second element in some manner. Also, unless stated otherwise, a set of elements may comprise of one or more elements. In addition, terminology of the form “at least one of: A, B, or C” used in the description or the claims means “A or B or C or any combination thereof” Those skilled in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those skilled would further appreciate that any of the various illustrative logical blocks, modules, processors, means, circuits, and algorithm steps described in connection with the aspects disclosed herein may be implemented as electronic hardware (e.g., a digital implementation, an analog implementation, or a combination of the two, which may be designed using source coding or some other technique), various forms of program or design code incorporating instructions (which may be referred to herein, for convenience, as “software” or a “software module”), or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the aspects disclosed herein.

The various illustrative logical blocks, modules, and circuits described in connection with the aspects disclosed herein may be implemented within or performed by an integrated circuit (“IC”), an access terminal, or an access point. The IC may comprise a general purpose processor, a digital signal processor (DSP), an application specific integrated circuit (ASIC), a field programmable gate array (FPGA) or other programmable logic device, discrete gate or transistor logic, discrete hardware components, electrical components, optical components, mechanical components, or any combination thereof designed to perform the functions described herein, and may execute codes or instructions that reside within the IC, outside of the IC, or both. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

It is understood that any specific order or hierarchy of steps in any disclosed process is an example of a sample approach. Based upon design preferences, it is understood that the specific order or hierarchy of steps in the processes may be rearranged while remaining within the scope of the aspects disclosed herein. The accompanying method claims present elements of the various steps in a sample order, and are not meant to be limited to the specific order or hierarchy presented.

The steps of a method or algorithm described in connection with the aspects disclosed herein may be embodied directly in hardware, in a software module executed by a processor, or in a combination of the two. A software module (e.g., including executable instructions and related data) and other data may reside in a data memory such as RAM memory, flash memory, ROM memory, EPROM memory, EEPROM memory, registers, a hard disk, a removable disk, a CD-ROM, or any other form of computer-readable storage medium known in the art. A sample storage medium may be coupled to a machine such as, for example, a computer/processor (which may be referred to herein, for convenience, as a “processor”) such the processor can read information (e.g., code) from and write information to the storage medium. A sample storage medium may be integral to the processor. The processor and the storage medium may reside in an ASIC. The ASIC may reside in user equipment. In the alternative, the processor and the storage medium may reside as discrete components in user equipment. Moreover, in some aspects any suitable computer-program product may comprise a computer-readable medium comprising codes (e.g., executable by at least one computer) relating to one or more of the aspects disclosed herein. In some aspects a computer program product may comprise packaging materials.

The previous description is provided to enable any person skilled in the art to understand fully the full scope of the disclosure. Modifications to the various configurations disclosed herein will be readily apparent to those skilled in the art. Thus, the claims are not intended to be limited to the various aspects of the disclosure described herein, but is to be accorded the full scope consistent with the language of claims, wherein reference to an element in the singular is not intended to mean “one and only one” unless specifically so stated, but rather “one or more.” Further, the phrase “at least one of a, b and c” as used in the claims should be interpreted as a claim directed towards a, b or c, or any combination thereof. Unless specifically stated otherwise, the terms “some” or “at least one” refer to one or more elements. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

While the foregoing disclosure discusses illustrative aspects and/or aspects, it should be noted that various changes and modifications could be made herein without departing from the scope of the described aspects and/or aspects as defined by the appended claims. Furthermore, although elements of the described aspects and/or aspects may be described or claimed in the singular, the plural is contemplated unless limitation to the singular is explicitly stated. Additionally, all or a portion of any aspect and/or aspect may be utilized with all or a portion of any other aspect and/or aspect, unless stated otherwise.

What is claimed is:

1. A method for encoding, the method comprising:
receiving a data signal;
performing a transform of the data signal to provide at least two coefficients; and
performing log companding of the at least two coefficients to provide a compressed data signal.

2. The method of claim 1, wherein the transform is one of a time-frequency decomposition and a time scale decomposition.

3. The method of claim 1, wherein the transform is a Discrete Cosine Transform (DCT) transform.

4. The method of claim 1, wherein the transform is a modified Discrete Cosine Transform (MDCT) transform.

5. The method of claim 1, wherein each coefficient is a spectral coefficient.

6. The method of claim 1, wherein the log companding comprises encoding the at least two coefficients using at least two companding parameters.

7. The method of claim 6, wherein the at least two companding parameter have the same value.

8. The method of claim 1, wherein the data signal is one of an audio signal, a speech signal and a biomedical signal.

9. A method for decoding, the method comprising:
receiving a compressed data signal;
performing inverse log companding by decoding the compressed data signal to obtain at least two coefficients; and
performing inverse transform on the at least two coefficients to provide a data signal.

10. The method of claim 9, wherein the inverse transform is one of an inverse time-frequency decomposition and an inverse time scale decomposition.

11. The method of claim 9, wherein the inverse transform is an inverse Discrete Cosine Transform (DCT) transform.

12. The method of claim 9, wherein the inverse transform is an inverse modified Discrete Cosine Transform (MDCT) transform.

13. The method of claim 9, wherein each coefficient is a spectral coefficient.

14. The method of claim 9, wherein the inverse log companding is performed by decoding the compressed data signal using at least two companding parameters.

15. The method of claim 14, wherein the companding parameters have the same value.

16. The method of claim 9, wherein the data signal is one of an audio signal, a speech signal and a biomedical signal.

17. An apparatus for encoding, the apparatus comprising:
a receiver configured to receive a data signal;
a transform circuit configured to decompose the data signal to provide at least two coefficients; and
a log companding circuit configured to encode the at least two coefficients to provide a compressed data signal.

18. The apparatus of claim 17, wherein the transform is one of a time-frequency decomposition and a time scale decomposition.

19. The apparatus of claim 17, wherein the transform is a DCT transform.

20. The apparatus of claim 17, wherein the transform is a modified DCT (MDCT) transform.

21. The apparatus of claim 17, wherein each coefficient is a spectral coefficient.

22. The apparatus of claim 17, wherein the log companding circuit encodes each coefficient using a different companding parameter.

23. The apparatus of claim 22, wherein the different companding parameter has the same value.

24. The apparatus of claim 17, wherein the data signal is one of an audio signal and a speech signal.

25. An apparatus for decoding, the apparatus comprising:
a receiver configured to receive a compressed data signal;
an inverse log companding circuit configured to decode the compressed data signal to obtain at least two coefficients; and
an inverse transform circuit configured to reconstruct a data signal from the at least two coefficients.

26. The apparatus of claim 25, wherein the inverse transform circuit is one of an inverse time-frequency decomposition and an inverse time scale decomposition.

27. The apparatus of claim 25, wherein the inverse transform circuit is an inverse DCT transform.

28. The apparatus of claim 25, wherein the inverse transform circuit is an inverse modified DCT (MDCT) transform.

29. The apparatus of claim 25, wherein each coefficient is a spectral coefficient.

30. The apparatus of claim 25, wherein the inverse log companding circuit decodes the compressed data signal using at least two companding parameters.

31. The apparatus of claim 30, wherein the companding parameters have the same value.

32. The apparatus of claim 25, wherein the data signal is one of an audio signal and a speech signal.

33. An apparatus for encoding, the apparatus comprising:
means for receiving a data signal;
means for performing a transform of the data signal to provide at least two coefficients; and
means for performing log companding of the at least two coefficients to provide a compressed data signal.

34. The apparatus of claim 33, wherein the transform is one of a time-frequency decomposition and a time scale decomposition.

35. The apparatus of claim 33, wherein the transform is a DCT transform.

36. The apparatus of claim 33, wherein the transform is a modified DCT (MDCT) transform.

37. The apparatus of claim 33, wherein each coefficient is a spectral coefficient.

38. The apparatus of claim 33, wherein the log companding is performed by encoding each coefficient using at least two companding parameters.

39. The apparatus of claim 38, wherein the companding parameters have the same value.

40. The apparatus of claim 33, wherein the data signal is one of an audio signal and a speech signal.

41. An apparatus for decoding, the apparatus comprising:
means for receiving a compressed data signal;
means for performing inverse log companding by decoding the compressed data signal to obtain at least two coefficients; and
means for performing inverse transform on the at least two coefficients to provide a data signal.

42. The apparatus of claim 41, wherein the inverse transform is one of an inverse time-frequency decomposition and an inverse time scale decomposition.

43. The apparatus of claim 41, wherein the inverse transform is an inverse DCT transform.

44. The apparatus of claim 41, wherein the inverse transform is an inverse modified DCT (MDCT) transform.

45. The apparatus of claim 41, wherein each coefficient is a spectral coefficient.

46. The apparatus of claim 41, wherein the inverse log companding is performed by decoding the compressed data signal using at least two companding parameters.

47. The apparatus of claim 46, wherein the companding parameters have the same value.

48. The apparatus of claim 41, wherein the data signal is one of an audio signal, a speech signal and a biomedical signal.

49. A computer program product for encoding, comprising:
a computer-readable medium encoded with instructions executable to:
receive a data signal;
perform a transform of the data signal to provide at least two coefficients; and
perform log companding of the at least two coefficients to provide a compressed data signal.

50. A computer program product for decoding, comprising:
a computer-readable medium encoded with instructions executable to:
receive a compressed data signal;
perform inverse log companding by decoding the compressed data signal to obtain at least two coefficients; and
perform inverse transform on the at least two coefficients to provide a data signal.

51. A headset comprising:
a receiver configured to receive a compressed data signal;
an inverse log companding circuit configured to decode the compressed data signal to obtain at least two coefficients;
an inverse transform circuit configured to reconstruct a data signal from the at least two coefficients; and
a transducer configured to provide audio output based on the reconstructed data signal.

52. A sensing device, comprising:
a sensor configured to detect a data signal;
a transform circuit configured to decompose the data signal to provide at least two coefficients;
a log companding circuit configured to encode the at least two coefficients to provide a compressed data signal; and
a transmitter configured to transmit the compressed data signal.

53. A handset, comprising:
a transducer configured to detect an audio signal;
a transform circuit configured to decompose the audio signal to provide at least two coefficients;
a log companding circuit configured to encode the at least two coefficients to provide a compressed audio signal; and
an antenna configured to transmit the compressed audio signal.

54. A watch, comprising:
a receiver configured to receive a compressed data signal;
an inverse log companding circuit configured to decode the compressed data signal to obtain at least two coefficients;
an inverse transform circuit configured to reconstruct a data signal from the at least two coefficients; and
a user interface configured to provide an indication based on the reconstructed data signal.
